(19) United States
(12) Patent Application Publication
(10) Pub. No.: US 2025/0169100 A1
(43) Pub. Date: May 22, 2025

(54) SEMICONDUCTOR DEVICE AND METHOD OF FORMING THEREOF

(71) Applicant: TAIWAN SEMICONDUCTOR MANUFACTURING COMPANY, LTD., Hsinchu (TW)

(72) Inventors: Tsung-Lin LEE, Hsinchu City (TW); Sen-Hong SYUE, Hsinchu County (TW); Yu-Ming CHEN, Taipei City (TW)

(73) Assignee: TAIWAN SEMICONDUCTOR MANUFACTURING COMPANY, LTD., Hsinchu (TW)

(21) Appl. No.: 18/511,721

(22) Filed: Nov. 16, 2023

(51) Int. Cl. H01L 29/78; H01L 21/02; H01L 21/762; H01L 29/06; H01L 29/417; H01L 29/66

(52) U.S. Cl. CPC H10D 30/62; H01L 21/02271; H01L 21/76229; H10D 30/0243; H10D 30/6219; H10D 62/116; H10D 64/017; H10D 64/021

(57) ABSTRACT

A method includes a number of operations. A plurality of isolation regions is formed between a plurality of fin structures over a substrate. A dummy gate structure is formed over the fin structures and the isolation regions. After forming the dummy gate structure, a first refilled isolation material is formed over the isolation regions. The first refilled isolation material is etched to form a plurality of first isolation layers having a top surface below top surfaces of the fin structures. A plurality of source/drain epitaxial structures is formed in the fin structures. The dummy gate structure is replaced with a gate structure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a Fin Field-Effect Transistor (FinFET), in accordance with some embodiments.

FIGS. 2 through 4 illustrate reference cross-section B-B illustrated in FIG. 1 that extends through a gate region along a longitudinal axis of the gate region or reference cross-section C-C illustrated in FIG. 1 that extends across the source/drain region.

FIGS. 5A, 13A, 14A, 15A, 16A, 17A and 18A illustrate reference cross-section A-A illustrated in FIG. 1 that extends through a fin structure along a longitudinal axis of the fin structure.

FIGS. 5B, 13B, 14B, 15B, 16B, 17B, 17C and 18B illustrate reference cross-section B-B illustrated in FIG. 1 that extends through a gate region along a longitudinal axis of the gate region.

FIGS. 5C through 12A, 12B, 13C, 14C, 14D and 18C illustrate reference cross-section C-C illustrated in FIG. 1 that extends across the source/drain regions.

FIG. 19 illustrates a diagram of compositions the refilled isolation material and the refilled isolation layers according to one or more embodiments of the present disclosure.

FIG. 20 is a diagram of wet etching rates (WER) and the refilled isolation layers according to one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

In order to avoid unintended electrical connections between different fin structures, isolation regions can be formed between multiple fin structures for the GAA transistor or the FinFETs. The isolation regions include, for example, shallow trench isolation (STI) structures. In one or more embodiments, one or more semiconductor processes (e.g, photolithography processes and/or etching processes) may be performed on the fin structures after the isolation regions are formed, and one or more source/drain structures or one or more gate structures are formed over the fin structures. The isolation regions between the fin structures may be unintentionally recessed due to the one or more semiconductor processes (e.g., etching process), and it causes the height of the top surface of the isolation regions to drop. As the heights of the top surfaces of the isolation regions decrease, neighboring source/drain epitaxial structures may unintentionally merged, causing unwanted shorting between adjacent transistors. To avoid unintended merger due to unwanted recessed profile of the isolation regions, in one or more embodiments, the height of the isolation regions may be compensated by refilling isolation layers over the isolation regions. However, since the spacing between the multiple fin structures may be different, loading effects occur in the recessed isolation regions, resulting in different heights at the top of the isolation regions between the different fin structures, and it is difficult to refill isolation layers over the isolation regions in a uniform and controlled manner. Therefore, in one or more embodiments, a flowable chemical vapor deposition process can be used to achieve compensation of the height of the etched isolation regions as far as possible without affecting other formed structures.

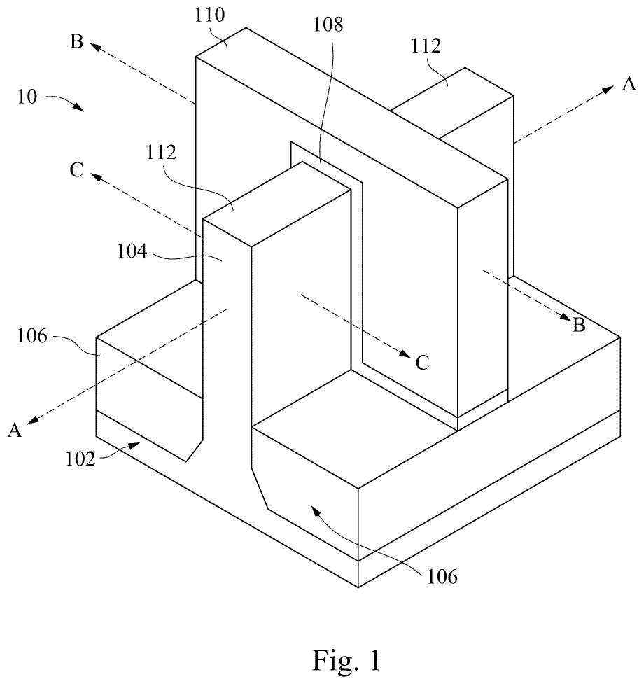

FIG. 1 illustrates an example of a FinFET 10 in a perspective view. The FinFET 10 includes a substrate 102 and a fin 104 protruding above the substrate 102. Isolation regions 106 are formed on opposing sides of the fin 104, with the fin 104 protruding above the isolation regions 106. A gate dielectric 108 is along sidewalls and over a top surface of the fin 104, and a gate electrode 110 is over the gate dielectric 108. Source/drain regions 112 are in the fin 104 and on opposing sides of the gate dielectric 108 and the gate electrode 110. FIG. 1 further illustrates reference cross-sections that are used in later figures. Cross-section B-B extends along a longitudinal axis of the gate electrode 110 of the FinFET 10. Cross-section A-A is perpendicular to cross-section B-B and is along a longitudinal axis of the fin 104 and in a direction of, for example, a current flow between the source/drain regions 112. Cross-section C-C is parallel to cross-section B-B and is across the source/drain region 112. Subsequent figures refer to these reference cross-sections for clarity.

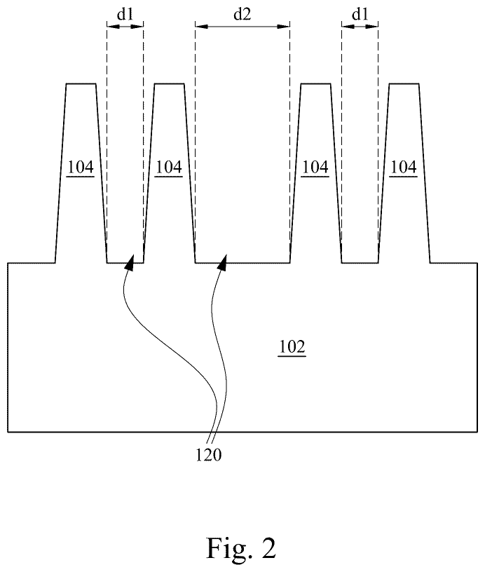

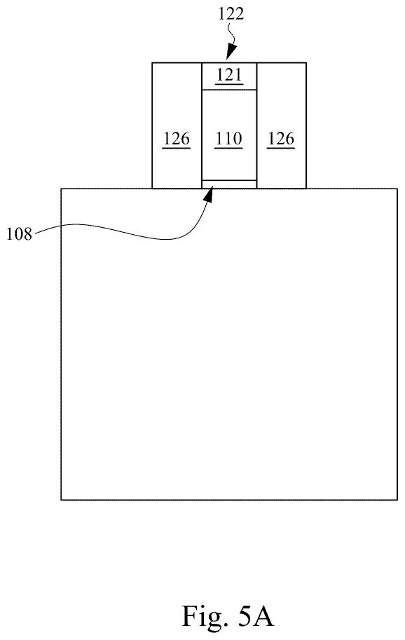

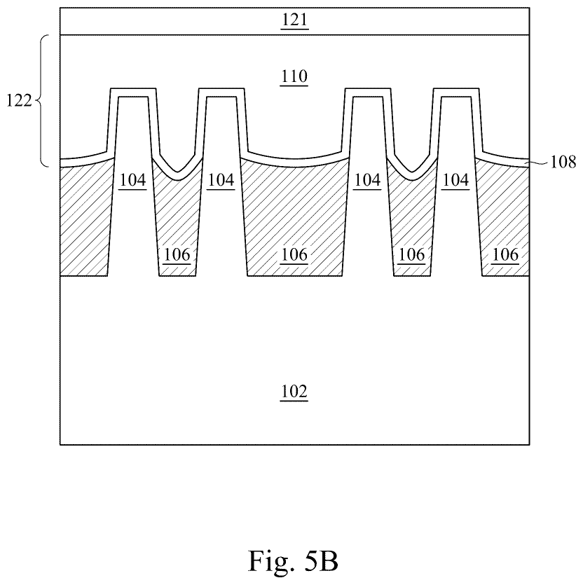

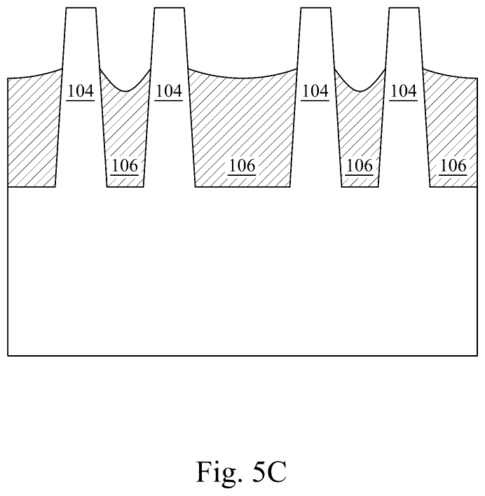

FIGS. 2 through 18C illustrate various views of a FinFET device 100 at various stages of fabrication, in accordance with an embodiment. FIGS. 2 through 4 illustrate reference cross-section B-B illustrated in FIG. 1 that extends through a gate region along a longitudinal axis of the gate region or reference cross-section C-C illustrated in FIG. 1 that extends across the source/drain region. FIGS. 5A, 13A, 14A, 15A, 16A, 17A and 18A illustrate reference cross-section A-A illustrated in FIG. 1 that extends through a fin structure. FIGS. 5B, 13B, 14B, 15B, 16B, 17B, 17C and 18B illustrate reference cross-section B-B illustrated in FIG. 1 that extends through a gate region along a longitudinal axis of the gate region. FIGS. 5C through 12A, 12B, 13C, 14C, 14D and 18C illustrate reference cross-section C-C illustrated in FIG. 1 that extends across the source/drain regions.

Reference is made to FIG. 2. FIG. 2 illustrates a cross-sectional view of a substrate 102. The substrate 102 may be a semiconductor substrate, such as a bulk semiconductor, a semiconductor-on-insulator (SOI) substrate, or the like, which may be doped (e.g., with a p-type or an n-type dopant) or undoped. The substrate 102 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 102 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

In some embodiments, the substrate 102 shown in FIG. 2 is patterned using, for example, photolithography and etching techniques. For example, a mask layer, such as a pad oxide layer and an overlying pad nitride layer, is formed over the substrate 102. The pad oxide layer may be a thin film comprising silicon oxide formed, for example, using a thermal oxidation process. The pad oxide layer may act as an adhesion layer between the substrate 102 and the overlying pad nitride layer and may act as an etch stop layer for etching the pad nitride layer. In some embodiments, the pad nitride layer is formed of silicon nitride, silicon oxynitride, silicon carbonitride, the like, or a combination thereof, and may be formed using low-pressure chemical vapor deposition (LPCVD) or plasma enhanced chemical vapor deposition (PECVD), as examples. The mask layer may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. In this example, the photoresist material is used to pattern the pad oxide layer and pad nitride layer to form a patterned mask. The patterned mask is subsequently used to pattern exposed portions of the substrate 102 to form trenches 120, thereby defining semiconductor fins 104 (may also be referred to as fins) between adjacent trenches 120 as illustrated in FIG. 2. In some embodiments, the semiconductor fins 104 are formed by etching trenches in the substrate 102 using, for example, reactive ion etch (RIE), neutral beam etch (NBE), the like, or a combination thereof. The etch may be anisotropic. In some embodiments, the trenches 120 may be strips (viewed from in the top) parallel to each other, and closely spaced with respect to each other. In some embodiments, the trenches 120 may be continuous and surround the semiconductor fins 104. After semiconductor fins 104 are formed, the patterned mask may be removed by etching or any suitable method.

The fins 104 may be patterned by any suitable method. For example, the fins 104 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins.

In FIG. 2, different distances d1 and d2 are between the semiconductor fins 104 in the horizontal direction. The distance d1 is between the left immediately-adjacent two of the semiconductor fins 104 or between the right immediately-adjacent two of the semiconductor fins 104 in the horizontal direction. The distance d2 is greater than the distance d1. In other words, each of the trenches 120 may have a width d1 or a width d2 in the horizontal direction.

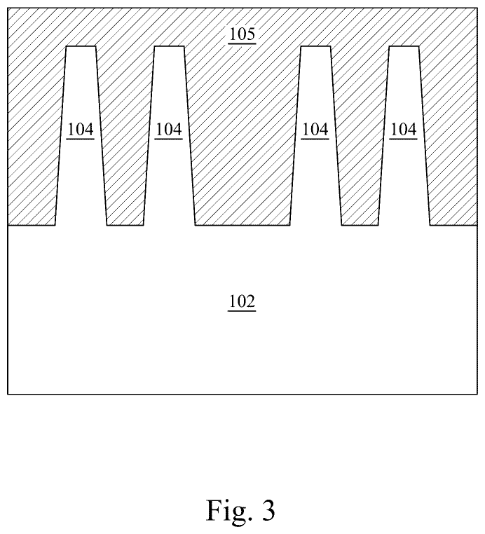

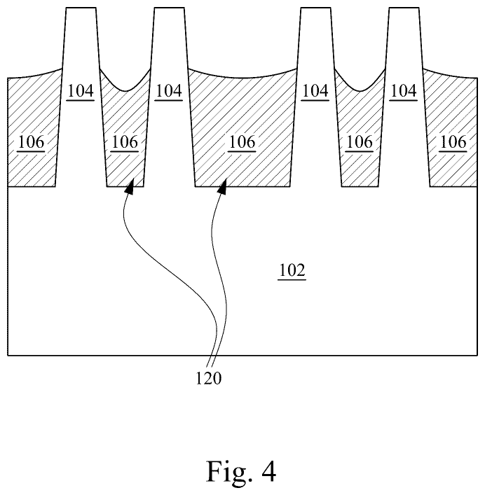

FIGS. 3 and 4 illustrate the formation of an insulation material 105 over and between neighboring semiconductor fins 104 to form isolation regions 106.

In FIG. 3, the insulation material 105 may be an oxide (e.g., silicon oxide), a nitride, the like, or a combination thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials and/or other formation processes may be used for the insulation material 105. An anneal process may be performed after the insulation material is formed. A planarization process, such as a chemical mechanical polish (CMP), may remove any excess insulation material (and, if present, the patterned mask) and form top surfaces of the isolation regions 106 and top surfaces of the semiconductor fins 104 that are coplanar (not shown).

Next, in FIG. 4, the insulation material 105 is recessed to form a plurality of isolation regions 106 between the semiconductor fins 104. The isolation regions 106 are recessed such that the upper portions of the semiconductor fins 104 protrude from between neighboring isolation regions 106. In other words, the isolation regions 106 are formed between the semiconductor fins 104. In some embodiments, the isolation regions 106 may be shallow trench isolation (STI) regions.

In some embodiments, the top surfaces of the isolation regions 106 may have a flat surface, a convex surface, a concave surface (as illustrated), or a combination thereof. The top surfaces of the isolation regions 106 may be formed flat, convex, and/or concave by an appropriate etch. The isolation regions 106 may be recessed using an acceptable etching process, such as one that is selective to the material of the isolation regions 106. For example, a chemical oxide removal using dilute hydrofluoric (dHF) acid may be used.

In one or more embodiments, loading effect appears on the isolation regions 106, and the top surfaces of the isolation regions 106 between the different semiconductor fins 104 may have different heights in the vertical direction. In FIG. 4, an isolation region 106 in the trench 120 with the distance d1 has a height less than a height of an isolation region 106 in the trench 120 with the distance d2 in the vertical direction. In some embodiments, as illustrated in FIG. 4, the isolation regions 106 have concave top surfaces, and different isolation regions 106 have different curvatures in their top surfaces. For example, top surface of the isolation regions 106 within the pattern-dense regions (i.e., regions with fins arranged with smaller pitch d1) has a greater curvature than top surface of the isolation regions 106 within the pattern-sparse regions (i.e., regions with fins arranged with larger pitch d2). Moreover, because of the pattern loading effect, lowest position of the concave top surface of the isolation regions 106 within the pattern-dense regions is lower than lowest position of the concave top surface of the isolation regions 106 within the pattern-sparse regions.

In some embodiments, fins may be formed in various different processes. In one example, a dielectric layer can be formed over a top surface of a substrate; trenches can be etched through the dielectric layer; homoepitaxial structures can be epitaxially grown in the trenches; and the dielectric layer can be recessed such that the homoepitaxial structures protrude from the dielectric layer to form fins. In another example, heteroepitaxial structures can be used for the fins. For example, the semiconductor fins can be recessed, and a material different from the semiconductor fins may be epitaxially grown in their place. In an even further example, a dielectric layer can be formed over a top surface of a substrate; trenches can be etched through the dielectric layer; heteroepitaxial structures can be epitaxially grown in the trenches using a material different from the substrate; and the dielectric layer can be recessed such that the heteroepitaxial structures protrude from the dielectric layer to form fins.

In some embodiments where homoepitaxial or heteroepitaxial structures are epitaxially grown, the grown materials may be in situ doped during growth, which may obviate prior and subsequent implantations although in situ and implantation doping may be used together. Still further, it may be advantageous to epitaxially grow a material in an NMOS region different from the material in a PMOS region. In various embodiments, the fins may comprise silicon germanium (SiₓGe₁₋ₓ, where x can be between approximately 0 and 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like.

FIGS. 5A-5C formation of dummy gate structures 122 over the semiconductor fins 104. The dummy gate structures 122 each include gate dielectric 108 and gate 110, in some embodiments. The dummy gate structure 122 may be formed by patterning a mask layer, a gate layer and a gate dielectric layer, where the mask layer, the gate layer and the gate dielectric layer comprise a same material as the mask 121, the gate 110, and the gate dielectric 108, respectively. To form the dummy gate structures 122, the gate dielectric layer is formed on the semiconductor fins 104 and the isolation regions 106. The gate dielectric layer may be, for example, silicon oxide, silicon nitride, multilayers thereof, or the like, and may be deposited or thermally grown according to acceptable techniques. The formation methods of the gate dielectric layer may include molecular-beam deposition (MBD), atomic layer deposition (ALD), plasma-enhanced CVD (PECVD), and the like.

The gate layer is formed over the gate dielectric layer, and the mask layer is formed over the gate layer. The gate layer may be deposited over the gate dielectric layer and then planarized, such as by a CMP. The mask layer may be deposited over the gate layer. The gate layer may be formed of, for example, polysilicon, although other materials may also be used. The mask layer may be formed of, for example, silicon nitride or the like.

After the gate dielectric layer, the gate layer, and the mask layer are formed, the mask layer may be patterned using acceptable photolithography and etching techniques to form mask 121. The pattern of the mask 121 may then be transferred to the gate layer and the gate dielectric layer by a suitable etching technique to form gates 110 and gate dielectrics 108, respectively. Each gate 110 and a corresponding gate dielectric 108 collectively serve as a dummy gate structure 122 that wrap around channel regions of the semiconductor fins 104. The gate 110 may also have a lengthwise direction substantially perpendicular to the lengthwise direction of respective semiconductor fins 104.

Still referring to FIGS. 5A-5C, after forming the dummy gate structures 122, gate spacers 126 are formed on opposing sidewalls of the gate structures 122. In some embodiments, the spacers 126 are formed in same processing. For example, a spacer material layer is first deposited as a blanket layer over the substrate, and then the spacer material layer is anisotropically etched, such that horizontal portions of the spacer material layer are removed, while leaving portions of the spacer material layer on respective sidewalls of the dummy gate structures 122. The remaining portions of the spacer material layer on sidewalls of the dummy gate structures 122 are denoted as gate spacers 126 as illustrated in FIG. 5A.

In some embodiments, the gate spacers 126 may be formed of a nitride (e.g., silicon nitride), silicon oxynitride, silicon carbide, silicon carbonitride, the like, or a combination thereof, and may be deposited using, e.g., CVD, ALD or other suitable deposition processes. In some embodiments where the spacer material layer includes silicon nitride, the patterning of the silicon nitride layer includes a dry etching using CH₂F₂ as an etchant. In other embodiments in which the spacer material layer includes a silicon oxide layer and a silicon nitride layer, the patterning of the spacer material layer includes a dry etching using CH₂F₂ as an etchant to pattern silicon nitride, followed by a dry etching using CF₄ as an etchant to pattern the silicon oxide layer. The patterning includes an anisotropic effect, so that the horizontal portions of the spacer material layer are removed, while some vertical portions on the sidewalls of the dummy gate structures 122 remain to form gate spacers 126.

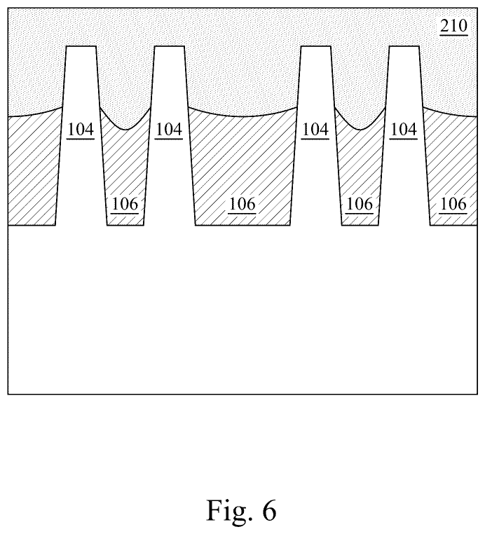

In one or more embodiments of the present disclosure, a plurality of refilled isolation layers 211 are formed over the isolation regions 106 and between the semiconductor fins 104 before formation of the source/drain regions 112, as illustrated in FIG. 6.

FIG. 6 shows the structure of FIG. 5C after formation of an isolation material 210, overlying the semiconductor fins 104 and the isolation regions 106 between the semiconductor fins 104 by a flowable chemical vapor deposition (FCVD) process, according to one or more embodiments of the present disclosure. Formation of the isolation material 210 by the FCVD process may include deposition of flowable dielectric material followed by a post-treatment process. For example, the post-treatment process may include high temperature (HT) sulfuric acid peroxide mixture (SPM), steam annealing or furnace baking, and different post-treatment process could reach different composition from nitride-like to oxide-like, depending on process needs for the isolation material 210.

Deposition of the flowable dielectric material may be performed using any deposition methods suitable for flowable dielectric materials (e.g., flowable silicon oxide, flowable silicon nitride, flowable silicon oxynitride, flowable silicon carbide, or flowable silicon oxycarbide). Flowable dielectric materials, as their name suggest, can “flow” during deposition to fill gaps or spaces with a high aspect ratio. Usually, various chemistries are added to silicon-containing precursors to allow the deposited film to flow. In some embodiments, nitrogen hydride bonds are added. Examples of flowable dielectric precursors, particularly flowable silicon oxide precursors, include a silicate, a siloxane, a methyl silsesquioxane (MSQ), a hydrogen silsesquioxane (HSQ), an MSQ/HSQ, a perhydrosilazane (TCPS), a perhydro-polysilazane (PSZ), a tetraethyl orthosilicate (TEOS), or a silyl-amine, such as trisilylamine (TSA). The flowable dielectric materials are formed in a FCVD process. For example, flowable silicon oxide may be deposited for the isolation material 210 using a FCVD process. The isolation material 210 formed through an FCVD process conformally covers the surface of the semiconductor fins 104 and the isolation regions 106 without any significant spaces or voids between the isolation material 210 and the isolation regions 106. Such a conformal deposition provides a filling effect, for example in recessed regions between fins 104. In some embodiments, flowability of the flowable dielectric material may be improved by precursor ratio (e.g., TSA/NH₃ ratio) adjustment to achieve selective bottom-up over the isolation regions 106 and less sidewall film deposition over the semiconductor fins 104 and the isolation regions 106.

Next, in a method of one or more embodiments of the present disclosure, a post-anneal process is performed on the isolation material 210. In some embodiments, a wet anneal process includes annealing the isolation material 210 at a temperature in a range from about 150° C. to about 1000° C. In some embodiments, a post-anneal process for the isolation material 210 includes annealing the isolation material 210 in steam at a temperature less than about 600° C. and may lead to different etch resistance capability to improve selectivity. In some embodiments, the post-anneal process for the isolation material 210 includes annealing the isolation material 210 in steam at a temperature less than about 600° C, less than about 450° C, less than about 400° C or even less than about 200° C. The low temperature (LT) annealing for the isolation material 210 is to avoid unintended damages of the semiconductor fins 104, the gate spacers 126 and the dummy gate structure 122.

In some embodiments, the post-annealing process of the isolation material 210 may be a wet anneal process. The wet anneal process facilitates conversion of the isolation material 210 into a Si—O bond network to form silicon oxide and/or substantially remove structural defects from the Si—O bond network by removing impurities, for example, residual nitrogen, hydrogen, carbon, compounds of hydrogen, compounds of carbon, or compounds of nitrogen that are present in the isolation material 210. These impurities may be residual precursor materials used in the deposition process or byproducts formed during the deposition process of the isolation material 210. In some embodiments, this wet annealing process reduces the flowable property of the isolation material 210 and partially converts the flowable dielectric material of the isolation material 210 into a dielectric material. Subsequent processing of the isolation material 210 as described below such as post-annealing and/or HT doping of the isolation material 210 densifies (e.g., solidifies) and converts the flowable material of the isolation material 210 into a dielectric material having negligible flowable properties. In some embodiments, the dielectric material is silicon oxide. In some embodiments, the dielectric material is silicon oxide having one or more residual impurities.

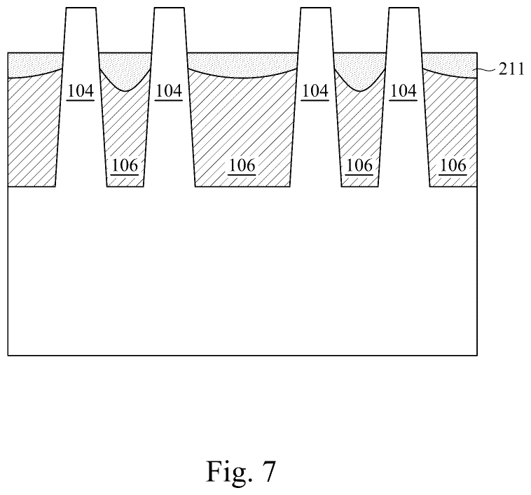

Continuing with FIG. 6, in FIG. 7, the isolation material 210 is etched back to expose the semiconductor fins 104. A plurality of isolation layers 211 is formed over the isolation regions 106 and between the semiconductor fins 104. In FIG. 7, the top surfaces of the formed isolation layers 211 have the same heights in the vertical direction. The isolation regions 106 and the isolation layers 211 may be commonly served as fin spacers used to limit formation of the source/drain regions 112. In some embodiments, the isolation layers 211 may be recessed using an acceptable etching process, such as one that is selective to the material of the isolation layers 211. For example, a chemical oxide removal using dilute hydrofluoric (dHF) acid may be used.

As shown in FIG. 7, in one or more embodiments, the isolation regions 106 and the isolation layers 211 form a plurality of bilayer isolation structures between the semiconductor fins 104. Top surfaces of the formed bilayer isolation structures may be level with each other. In one or more embodiments of the present disclosure, the isolation layers 211 include silicon oxide and impurity doped into silicon oxide during formation of the isolation layers 240. In one or more embodiments of the present disclosure, a concentration of oxygen of the isolation layers 211 is less than a concentration of oxygen of the isolation regions 106.

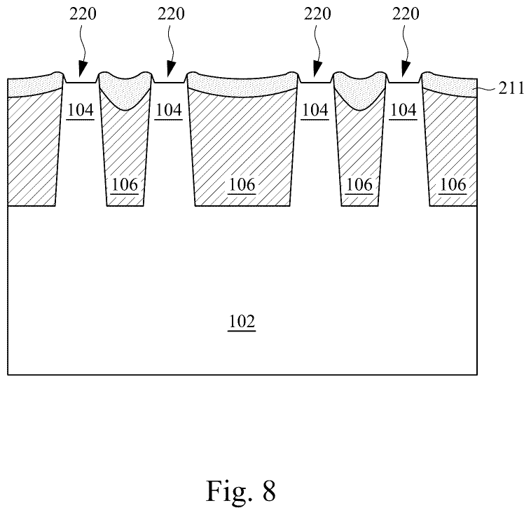

Next, in FIG. 8, the exposed portions of the fins 104 can be recessed using suitable selective etching processing that attacks the semiconductor fin 104, but hardly attacks the gate spacers 126, the isolation regions 106 and the isolation layers 211 served as fin spacers, and the top masks 121 of the dummy gate structures 122. The source/drain recesses 220 are formed over the semiconductor fins 104. As shown in FIG. 8, the refilled isolation layers 211 between the semiconductor fins 104 may be partially etched during the semiconductor fins 104 are etched to form the source/drain recesses 220. However, most of the isolation layers 211 remains and have bottom surfaces higher than bottoms of the source/drain recesses 220 over the semiconductor fins 104. In FIG. 8, the isolation layers 211 have top surfaces more planar than bottom surfaces of the isolation layers 211. In some embodiments, profiles of the bottom surfaces of the isolation layers 211 are similar to top surfaces of the isolation regions 106.

In some embodiments, recessing the semiconductor fins 104 may be performed by a dry chemical etch with a plasma source and an etchant gas. The plasma source may be inductively coupled plasma (ICR) etch, transformer coupled plasma (TCP) etch, electron cyclotron resonance (ECR) etch, reactive ion etch (RIE), or the like and the etchant gas may be fluorine, chlorine, bromine, combinations thereof, or the like, which etches the semiconductor fins 104 at a faster etch rate than it etches the gate spacers 126, fin spacers 128, and the top masks 121 of the dummy gate structures 122. In some other embodiments, recessing the semiconductor fins 104 may be performed by a wet chemical etch, such as ammonium peroxide mixture (APM), NH₄OH, tetramethylammonium hydroxide (TMAH), combinations thereof, or the like, which etches the semiconductor fins 104 at a faster etch rate than it etches the gate spacers 126, the isolation regions 106 and the isolation layers 211 served as fin spacers, and the top masks 121 of the dummy gate structures 122. In some other embodiments, recessing the semiconductor fins 104 may be performed by a combination of a dry chemical etch and a wet chemical etch.

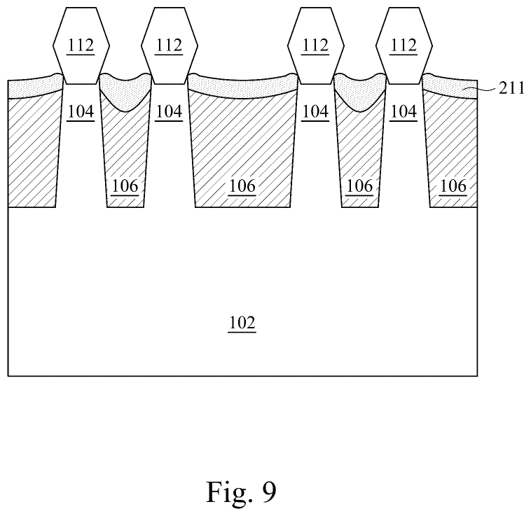

Reference is made to FIG. 9. Once the source/drain recesses 220 are created in the exposed regions of the fins 104, structures of epitaxial source/drain regions 112 are formed in the source/drain recesses in the fins 104 to serve as source/drain regions 112 of transistors, by using one or more epitaxy or epitaxial (epi) processes that provides one or more epitaxial materials on the semiconductor fins 104. In FIG. 9, the source/drain regions 112 are formed on exposed portions of the fins that are not covered by the dummy gate structures 122 and gate spacers 126. In some embodiments, formation of the source/drain regions 112 includes etching exposed portions of the fins 104 to form a plurality of source/drain recesses 220 in the fins 104, followed by epitaxially growing semiconductor materials in the recesses of the fins 104.

During the epitaxial growth process, the gate spacers 126 and the isolation regions 106 and the isolation layers 211 served as fin spacers limit the one or more epitaxial materials to exposed regions in the fins 104. As illustrated in FIG. 9, the epitaxial source/drain regions 112 may have surfaces raised from respective surfaces of the fins 104 (e.g. raised above the non-recessed portions of the fins 104) and may have facets. In some embodiments, the source/drain regions 112 epitaxially grown on adjacent fins 104 do not merge together and remain separate source/drain regions 112, as illustrated in FIG. 9, because the epitaxial growth is constrained by the isolation layers 211.

In some embodiments, as illustrated in FIG. 9, the epitaxial material may be confined by the fin recess between corresponding fin spacers of the isolation regions 106 and the isolation layers 211 and thus may have straight vertical or sloping sidewalls in between the isolation layers 211. Once the epitaxial material is grown to above the isolation layers 211, the epitaxial material will not be limited by the isolation regions 106 and the isolation layers 211 served as fin spacers and thus form facets to have diamond shape. As a result, when viewed in a cross-sectional view taken along a direction perpendicular to longitudinal axes of fins 104 (e.g., FIG. 9), each source/drain region 112 grown from a fin 104 has a lower portion confined between a corresponding pair of the isolation layers 211 and/or between a corresponding pair of the isolation regions 106. Each source/drain region 112 grown from a fin 104 has an upper portion 112u free of confinement by the corresponding pair of the isolation layers 211. In FIG. 9, each source/drain region 112 having a lower portion in the source/drain recess 220 and an upper portion raised from the isolation layers 211 is with a hexagonal cross-sectional profile. In some embodiments, the upper portions of the source/drain region 112 may have different cross-sectional profiles than the lower portions. In some embodiments, the upper portion of each source/drain region 112 has a diamond cross-sectional profile, and the lower portion of each source/drain region 112 has a rectangular cross-sectional profile or a trapezoidal cross-sectional profile.

In some embodiments, the lattice constants of the epitaxy material of source/drain regions 112 are different from the lattice constant of the semiconductor fins 104, so that the channel regions in the fins 104 and between the source/drain regions 112 can be strained or stressed by the epitaxial material to improve carrier mobility of the semiconductor device and enhance the device performance. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the semiconductor fins 104.

In some embodiments, the source/drain regions 112 may include Ge, Si, GaAs, AlGaAs, SiGe, GaAsP, SiP, or other suitable material. The source/drain regions 112 may be in-situ doped during the epitaxial process by introducing doping species including: p-type dopants, such as boron or BF₂; n-type dopants, such as phosphorus or arsenic; and/or other suitable dopants including combinations thereof. If the source/drain epitaxial structures 112 are not in-situ doped, an implantation process (i.e., a junction implant process) is performed to dope the source/drain epitaxial structures 112. In some exemplary embodiments, the source/drain epitaxial structures 112 in an n-type transistor include SiP, while those in a p-type include GeSnB and/or SiGeSnB. In embodiments with different device types, a mask, such as a photoresist, may be formed over n-type device regions, while exposing p-type device regions, and p-type epitaxial structures may be formed on the exposed fins 104 in the p-type device regions. The mask may then be removed. Subsequently, a mask, such as a photoresist, may be formed over the p-type device region while exposing the n-type device regions, and n-type epitaxial structures may be formed on the exposed fins 104 in the n-type device region. The mask may then be removed.

Once the source/drain regions 112 are formed, an annealing process can be performed to activate the p-type dopants or n-type dopants in the source/drain regions 112. The annealing process may be, for example, a rapid thermal anneal (RTA), a laser anneal, a millisecond thermal annealing (MSA) process or the like.

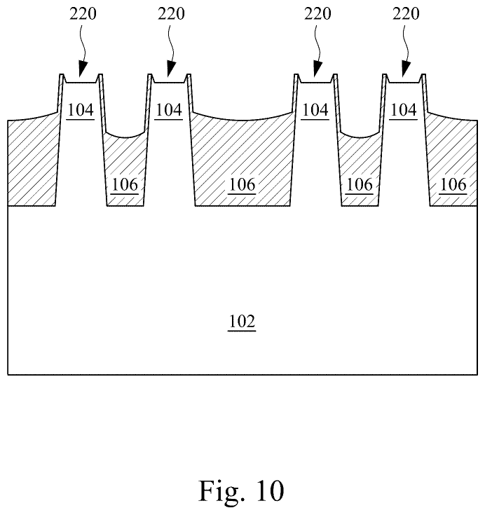

FIGS. 10 through 12A and 13A through 13C illustrate formation of source/drain regions 112 over the semiconductor fins 104 after the dummy gate structure 122 is formed according to one or more embodiments of the present disclosure, wherein a plurality of refilled isolation layers 211 are formed over the isolation regions 106 and between the semiconductor fins 104 during formation of the source/drain regions 112. Differences of the formation flow of FIGS. 10 through 13C and the formation flow of FIGS. 6-9 include that the refilled isolation layers 211 are formed after the source/drain recesses 220 are formed over the semiconductor fins 104. For the sake of clarity, in FIGS. 10 through 13C, some details of forming similar layers or structures would not repeat.

Continuing with FIGS. 5A though 5C, in FIG. 10, recessing the semiconductor fins 104 to form a plurality of source/drain recesses 220 recessed from top surfaces of the semiconductor fins 104. As shown in FIG. 10, the isolation regions 106 may be etched during the semiconductor fins 104 are etched. Portions of the isolation regions 106 over sidewalls of the semiconductor fins 104 remain so that the isolation regions 106 have tops higher than bottoms of the source/drain recesses 220. The remaining portions of the isolation regions 106 over the sidewalls of the semiconductor fins 104 may be served as fin spacers used to limit formation of the source/region regions 112. In FIG. 10, loading effect appears on the isolation regions 106 after the isolation regions 106 are etched during the semiconductor fins 104 are etched. Bottoms of the isolation regions 106 between different semiconductor fins 104 may have different heights in the vertical direction. Reference is made to FIG. 2 and FIG. 10. The bottom of each isolation region 106 in the trench 120 with the distance d1 is lower than the bottom of each isolation region 106 in the trench 120 with the distance d2.

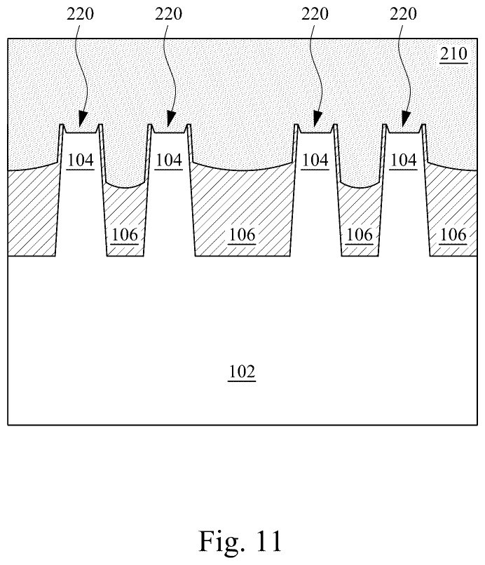

Since the isolation regions 106 are etched during the semiconductor fins 104 are etched, gaps are provided between the source/drain recesses 220. In order to avoid unintended mergers of the immediately-adjacent source/drain regions 112, a plurality of isolation layers 211 may be refilled in the gaps between the source/drain recesses 220. FIG. 11 illustrates forming isolation material 210 over the isolation regions 106 and the semiconductor fins 104. As shown in FIG. 11, the source/drain recesses 220 over the semiconductor fins 104 are temporarily refilled with the isolation martial 210. In some embodiments, the isolation material 210 is formed by a flowable CVD process and is uniformly flat.

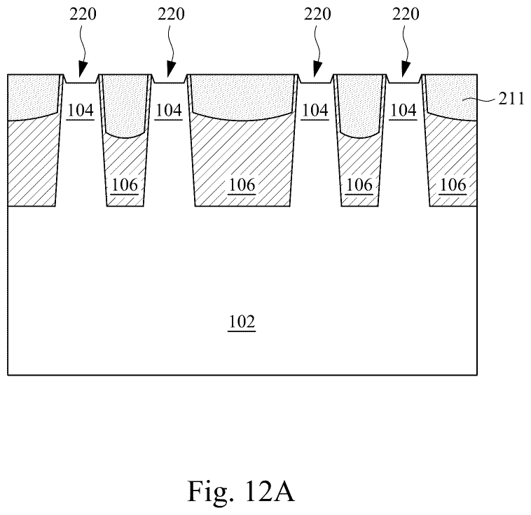

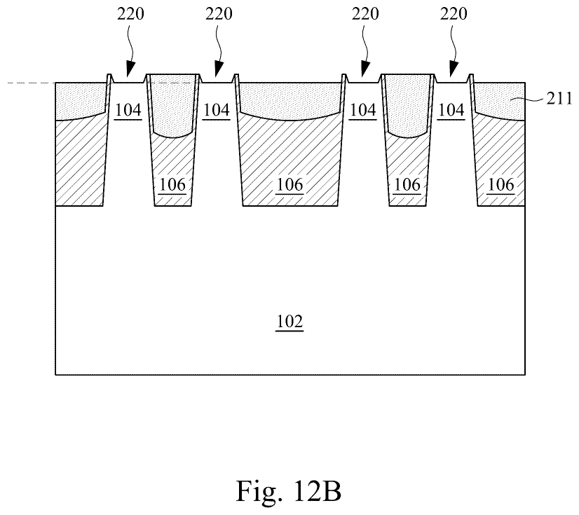

Next, in FIG. 12A, the isolation material 210 is etched back to expose the source/drain regions 220. The refilled isolation material 210 in the source/drain recesses 220 is removed. A plurality of isolation layers 211 is over the isolation regions 106 and between the semiconductor fins 104. In FIG. 12A, the top surfaces of the formed isolation layers 211 have the same heights and are higher than the bottoms of the source/drain recesses 220 in the vertical direction. The isolation layers 211 have top surfaces more planar than bottom surfaces of the isolation layers 211. As shown in FIG. 12A, the refilled isolation layers 211 are spaced apart from the source/drain recesses 220 by the isolation regions 106 remaining on the sidewalls of the semiconductor fins 104. The isolation regions 106 remaining on the sidewalls of the semiconductor fins 104 and the isolation layers 211 may be commonly served as fin spacers used to limit formation of the source/drain regions 112.

FIG. 12B illustrates reference cross-section C-C illustrated in FIG. 1 that extends across the source/drain regions. Differences between the structure shown in FIG. 12A and the structure shown in FIG. 12B include that in FIG. 12B heights of the top surfaces of the isolation layers 211 may be different in different positions between the semiconductor fins 104 in the vertical direction. In FIG. 12B, the top surfaces of the isolation layers 211 may be flat since the isolation layers 211 are formed by a flowable CVD process and etching back process, and the heights of the top surfaces of the isolation layers 211 in different positions are controllable.

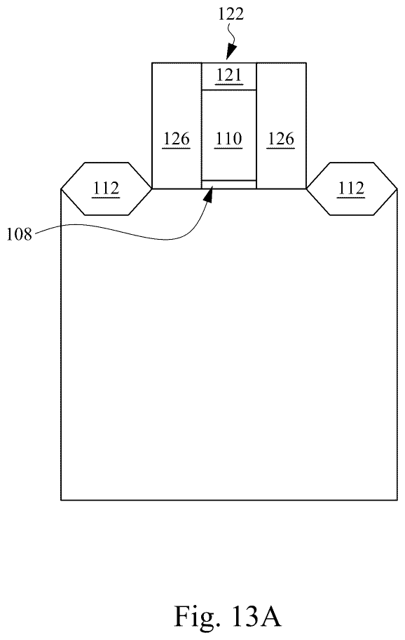

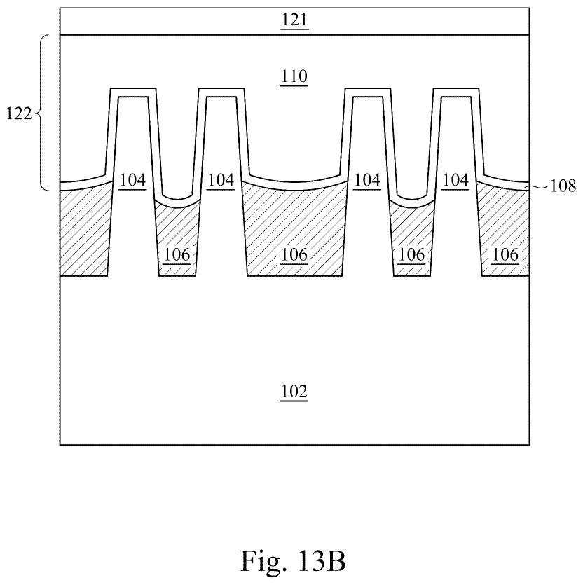

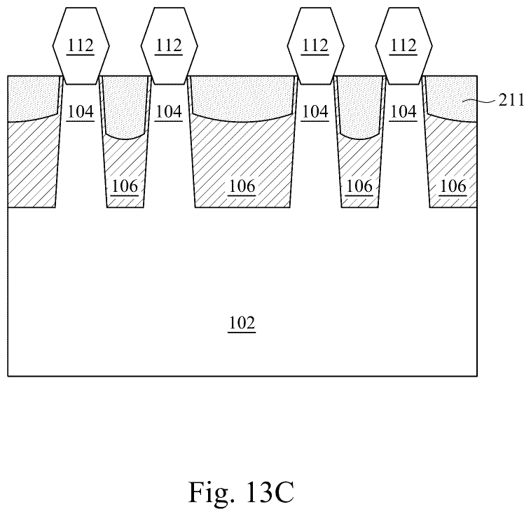

Continuing with FIG. 12A, reference is made to FIGS. 13A through 13C. After the isolation layers 211 are formed over the isolation regions 106 to compensate the heights of the recessed isolation regions 106, source/drain regions 112 are formed in the source/drain recesses 220 and raise from the isolation regions 106 and the isolation layers 211, wherein edges of the formed source/drain regions 112 are limited by the isolation regions 106 and the isolation layers 211 served as fin spacers. As shown in FIG. 13C, the source/drain regions 112 over the immediately-adjacent two of the semiconductor fins 104 do not merge together.

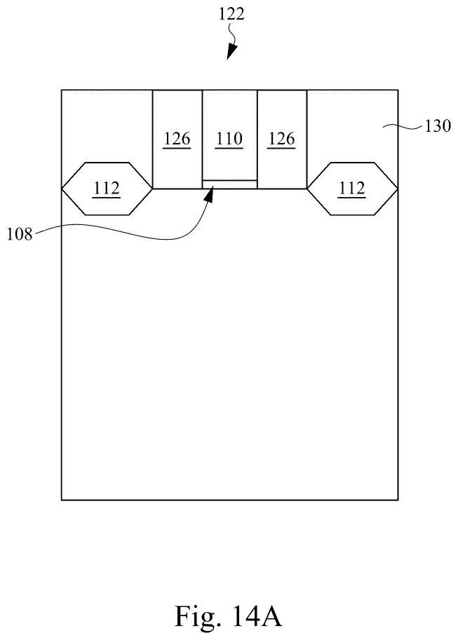

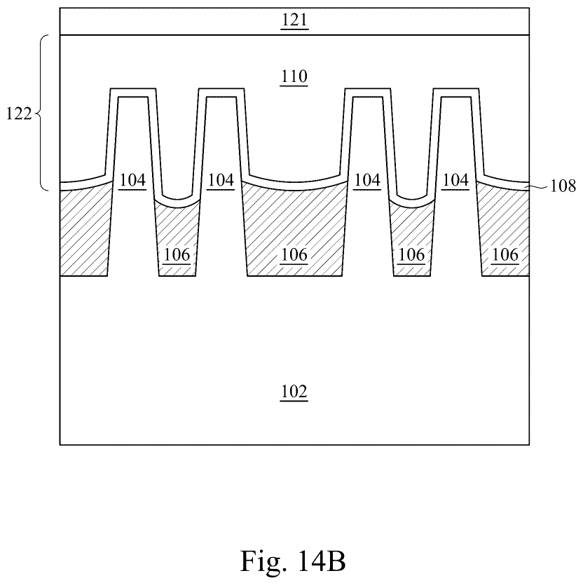

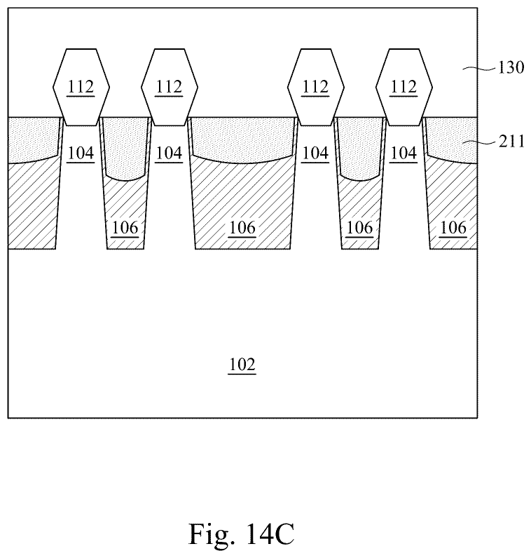

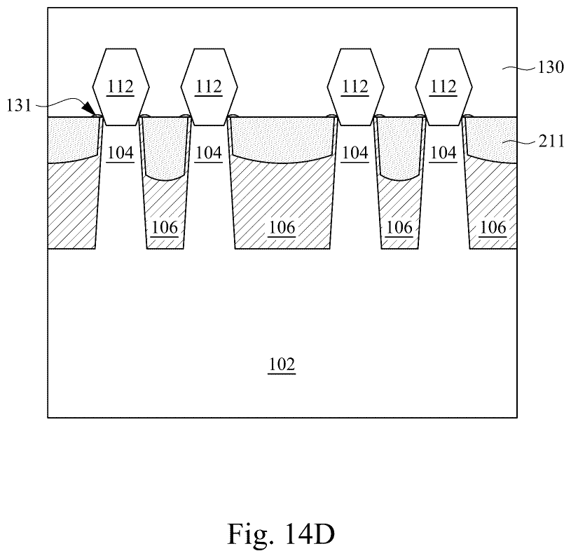

FIGS. 14A through 14C illustrate formation of an interlayer dielectric (ILD) layer 130 over the source/drain regions 112. In some embodiments, the ILD layer 130 is formed of a dielectric material such as silicon oxide (SiO₂), phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. A planarization process, such as CMP, may be performed to planarize the top surface of the ILD layer 130 and the dummy gate structure 122, such that the top surface of the ILD layer 130 is level with the top surface of the dummy gate structure 122 after the CMP process.

In some embodiments, the ILD layer 130 is formed of a dielectric material such as silicon oxide (SiO₂), phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. A planarization process, such as CMP, may be performed to planarize the top surface of the ILD layer 130. In some embodiments, a planarization process, such as CMP, may be performed to remove the mask 121 and to planarize the top surface of the ILD layer 130, such that the top surface of the ILD layer 130 is level with the top surface of the gate 110 after the CMP process, and the top surface of the gate 110 is exposed after the CMP process.

FIG. 14D illustrate reference cross-section C-C illustrated in FIG. 1 that extends across the source/drain regions 112. Differences between the structure shown in FIG. 14C and the structure shown in FIG. 14D include that in FIG. 14D a plurality of air gaps 131 are formed between the top surfaces of the isolation layers 211 and the ILD layers 130. In FIG. 14D, the air gaps 131 may be formed adjacent corners of the source/drain regions 112 and the isolation layers 211.

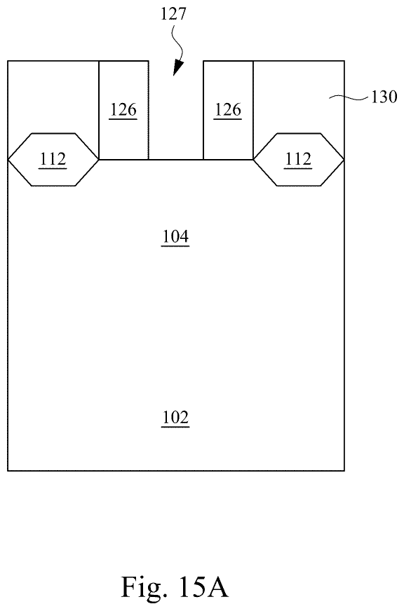

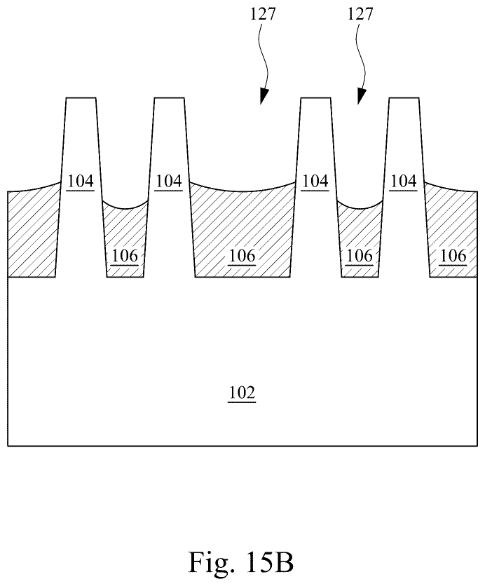

Continuing with FIGS. 14A through 14C, as illustrated in FIGS. 15A and 15B, a gate-last process (sometimes referred to as replacement gate process) is performed and the dummy gate structure 122 including the gate dielectric 108 and the gate 110 are respectively removed. In a gate-last process, the gate 110 and the gate dielectric 108 (see FIG. 14B), which are considered dummy gate and dummy gate dielectric, respectively, are removed and may be replaced with an active gate and an active gate dielectric, which may be collectively referred to as a replacement gate.

In accordance with some embodiments, the gate 110 and the gate dielectric 108 directly under the gate 110 are removed in an etching step(s), so that a gate trench 127 is formed between a corresponding pair of gate spacers 126. The gate trench 127 exposes a channel region of a respective fin 104. Each channel region may be disposed between neighboring pairs of epitaxial source/drain regions 112. During the dummy gate removal, the dummy gate dielectric layer 108 may be used as an etch stop layer when the dummy gate 110 is etched. The dummy gate dielectric layer 108 may then be removed after the removal of the dummy gate 110.

As shown in FIG. 15A, the semiconductors fins 104 are exposed from the gate trench 127 formed by a pair of the gate spacer 126. In a cross-section view across one or more gate regions of the semiconductor fins 104 of FIG. 15B, the semiconductor fins 104 and the isolation regions 106 between the gate spacers 126 are exposed. In one or more embodiments of the present disclosure, the isolation regions 106 may be etched during the dummy gate structure 122 are etched and removed. In FIG. 15B, the accumulation of etching appears on the isolation regions 106 in different positions, and bottoms of the exposed isolation regions 106 between different semiconductor fins 104 may have different heights in the vertical direction.

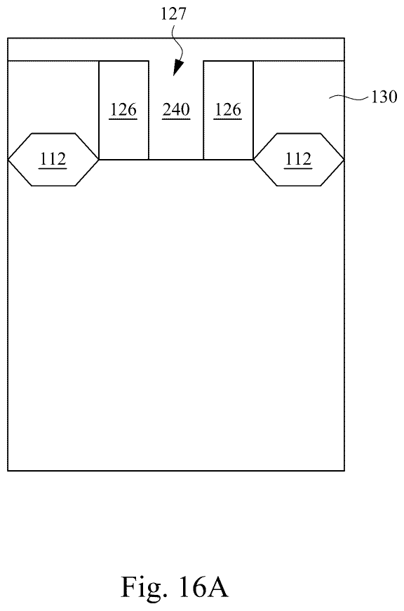

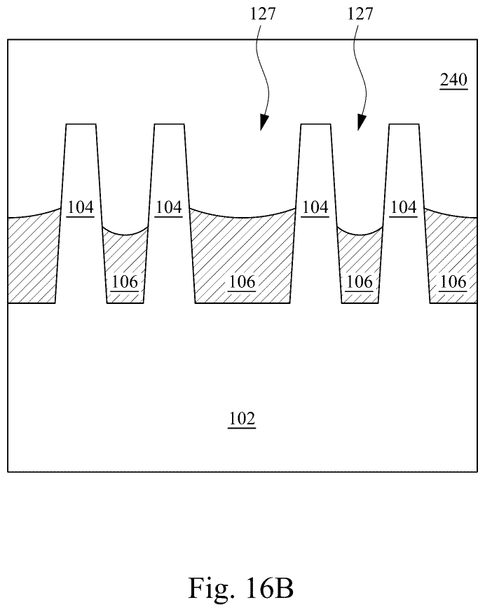

FIGS. 16A and 16B illustrates cross-section views of refilling isolation material 240 in the gate trench 127 and over the gate spacer 127, the semiconductor fins 104 and the isolation regions 106 near the exposed fins 104. In some embodiments, the isolation material 240 may be an oxide (e.g., silicon oxide). In some embodiments, the isolation material 240 is formed by a FCVD process and is uniformly flat. In some embodiments, formation of the isolation material 240 by the FCVD process may include deposition of flowable dielectric material followed by a post-treatment process. For example, the post-treatment process may include high temperature (HT) sulfuric acid peroxide mixture (SPM), steam annealing or furnace baking, and different post-treatment process could reach different composition from nitride-like to oxide-like, depending on process needs for the isolation material 240. In some embodiments, the formation of the isolation material 240 may be similar to formation of the isolation material 210.

In FIG. 16A, the top surface of the refilled isolation material 240 is higher than the top surface of the gate spacer 126 and the ILD layer 130 in the vertical direction. In FIG. 16B, observable interfaces present between the refilled isolation material 240 and the isolation regions 106.

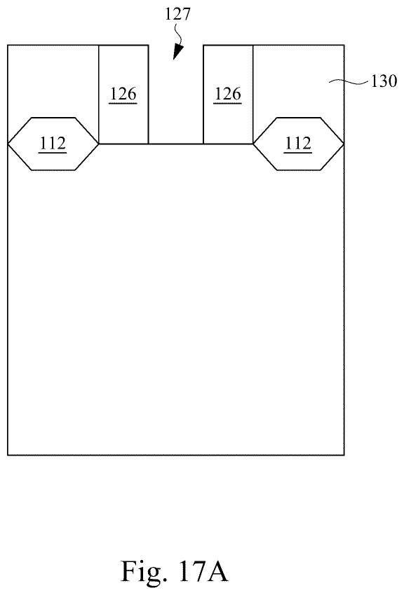

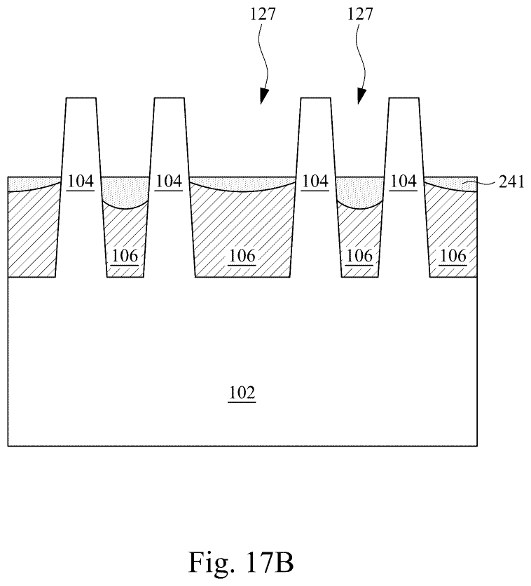

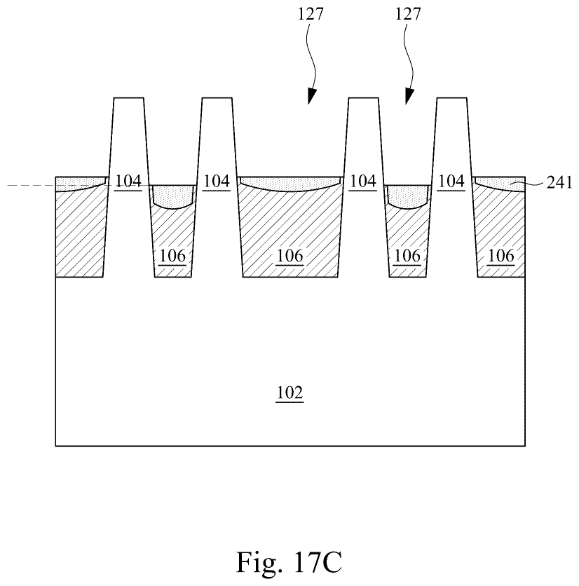

Next, in FIGS. 17A and 17B, the isolation material 240 is etched back to expose the semiconductor fins 104. The isolation material 240 higher than the top surfaces of the semiconductor fins 104 are removed. A plurality of isolation layers 241 is formed over the isolation regions 106 and between the semiconductor fins 104. The isolation layers 241 are lower than the top surface of the semiconductor fins 104. In FIG. 17B, the isolation layers 241 have top surfaces more planar than bottom surfaces of the isolation layers 241. In some embodiments, the top surfaces of the formed isolation layers 241 have the same or similar heights in the vertical direction. In some embodiments, the isolation layers 241 may be recessed using an acceptable etching process, such as one that is selective to the material of the isolation layers 241. For example, a chemical oxide removal using dilute hydrofluoric (dHF) acid may be used.

Similar to the isolation regions 106 and the isolation layers 211, in one or more embodiments, the isolation regions 106 and the isolation layers 241 form a plurality of bilayer isolation structures between the semiconductor fins 104. Top surfaces of the formed bilayer isolation structures may be level with each other. In one or more embodiments of the present disclosure, the isolation layers 241 include silicon oxide and impurity doped into silicon oxide during formation of the isolation layers 240. In one or more embodiments of the present disclosure, a concentration of oxygen of the isolation layers 241 is less than a concentration of oxygen of the isolation regions 106.

FIG. 17C illustrates reference cross-section B-B illustrated in FIG. 1 that extends through a gate region along a longitudinal axis of the gate region. Differences between the structure shown in FIG. 17B and the structure shown in FIG. 17C include that in FIG. 17C heights of the top surfaces of the isolation layers 241 may be different in different positions between the semiconductor fins 104 in the vertical direction. In FIG. 17C, the top surfaces of the isolation layers 241 may be flat since the isolation layers 241 are formed by a flowable CVD process and etching back process, and the heights of the top surfaces of the isolation layers 241 in different positions are controllable and have different heights.

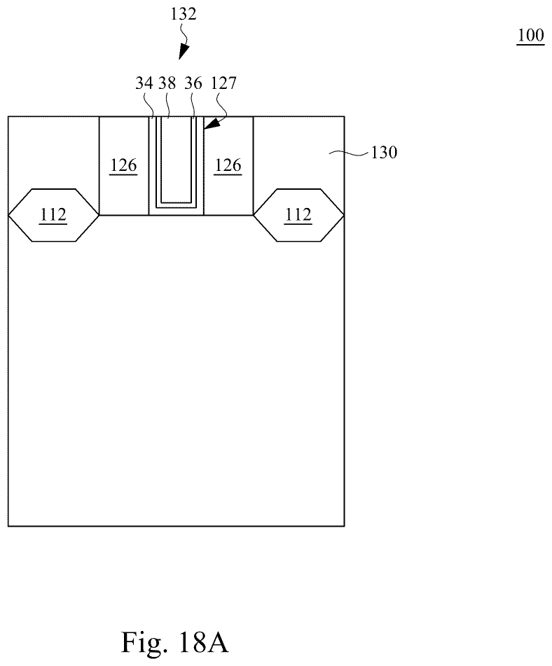

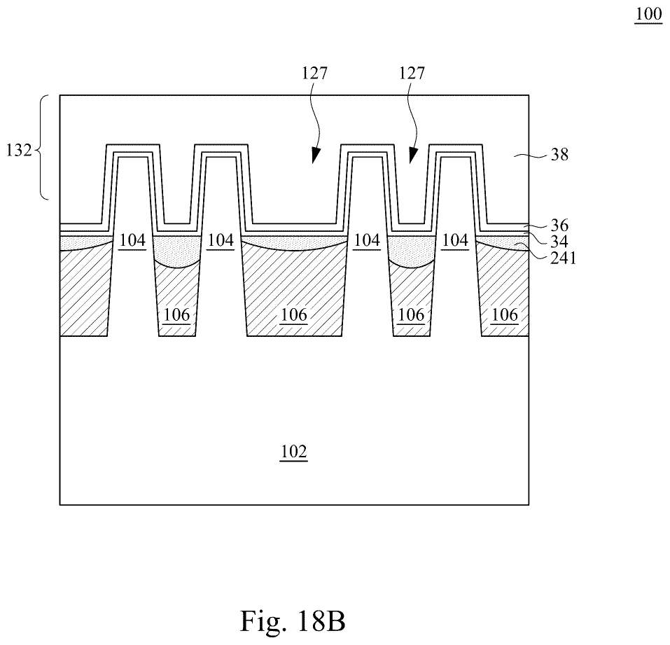

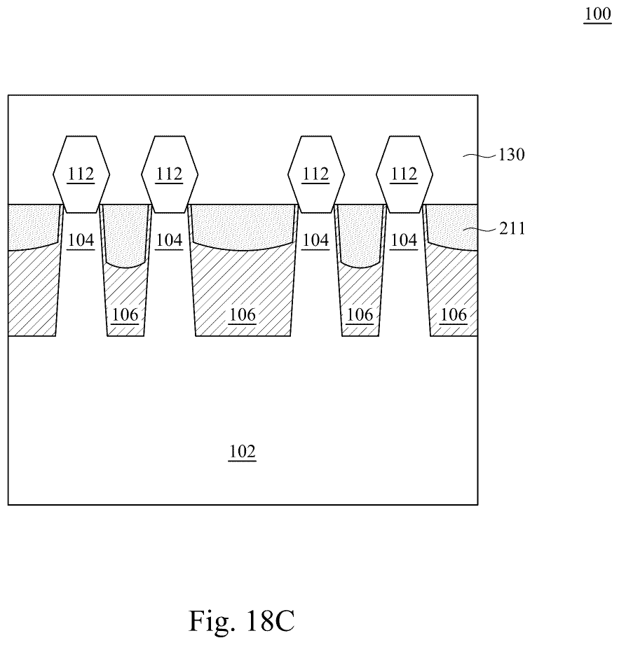

Continuing with FIGS. 17A and 17B, FIGS. 18A through 18C illustrate cross-section views of forming gate structure 132 replacing the dummy gate structure 122. In FIGS. 18A through 18C, replacement gate structures 132 are formed in respective gate trenches between pairs of the gate spacers 126. The replacement gate structures 132 may be the final gates of FinFETs. The final gate structures each may be a high-k/metal gate stack, however other compositions are possible. In some embodiments, each of the replacement gate structures 132 forms the gate associated with the three-sides of a channel region provided by the fins 104. Stated another way, each of the replacement gate structures 132 wraps around channel regions of the fins 104 on three sides.

High-k/metal gate structures 132 are formed in the gate trenches by forming a gate dielectric layer 34, a work function metal layer 36, and a gate electrode 38 successively in each of the gate trenches. As illustrated in FIGS. 18A through 18C, the gate dielectric layer 34 is deposited conformally in the gate trenches. The work function metal layer 36 is formed conformally over the gate dielectric layer 34, and the gate electrode 38 fills the recesses. The gate dielectric layer 34 includes an interfacial layer (e.g., silicon oxide layer) and a high-k gate dielectric layer over the interfacial layer. High-k gate dielectrics, as used and described herein, include dielectric materials having a high dielectric constant, for example, greater than that of thermal silicon oxide (−3.9). The work function metal layer 36 and/or gate electrode 38 used within high-k/metal gate structures 132 may include a metal, metal alloy, or metal silicide. Formation of the high-k/metal gate structures 132 may include multiple deposition processes to form various gate materials, one or more liner layers, followed by one or more CMP processes to remove excessive gate materials. After the one or more CMP processes are complete, gate materials remain in the gate trenches to serve as high-k/metal gate structures 132.

In some embodiments, the interfacial layer of the gate dielectric layer 34 may include a dielectric material such as silicon oxide (SiO₂), HfSiO, or silicon oxynitride (SiON). The interfacial layer may be formed by chemical oxidation, thermal oxidation, atomic layer deposition (ALD), chemical vapor deposition (CVD), and/or other suitable method. The high-k dielectric layer of the gate dielectric layer 34 may include hafnium oxide (HfO₂). Alternatively, the gate dielectric layer 34 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof.

The work function metal layer 36 may include work function metals to provide a suitable work function for the high-k/metal gate structures 132. For an n-type FinFET, the work function metal layer 36 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type FinFET, the work function metal layer 3 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the gate electrode 38 may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In FIGS. 18A and 18B, the metal gate structures 132 is illustrated as an example. However, one or more metal gate structures 132 may be used to form the FinFET device 100, as skilled artisans readily appreciate.

FIG. 18B illustrates the isolation layers 241 between the gate spacers 126. FIG. 18C illustrates the isolation layers 211 between the gate spacers 126. The isolation layers 211 spaced apart from the isolation layers 241 by the gate spacers 126 in a longitudinal direction of the semiconductor fins 104.

As shown in FIGS. 18A through 18C, the FinFET device 100 is formed and includes the refilled isolation layers 211 near the source/drain regions 112 and the refilled isolation layers 241 near the gate structure 132. Formation of the refilled isolation layers 211 is to avoid unintended merger of the adjacent source/drain regions 112 over the different semiconductor fins. Loading effect of the isolation regions 106 near the gate structure 132 is improved by forming the isolation layers 241 to compensate loss of the isolation regions 106 after one or more semiconductor etching process are performed.

In some embodiments, in the FinFET device, the refilled isolation layers 211 can only be formed near the source/drain regions 112 to avoid unintended merger of the epitaxial source/drain regions 112. In some embodiments, the FinFET device can only form refilled isolation layers 241 near the gate structure 132 to improve the loading effect of the isolation regions 106 near the gate structure 132. In one or more implementations, it may be determined whether to perform the FCVD refilling process of the isolation layers 211 near the source/drain regions 112 or the isolation layers 241 near the gate structures 132 according to the height of the top surface of the isolation regions 106 near the source/drain regions 112 and the gate structure 132, thereby avoiding that the source/drain regions 112 merges and improving loading effect.

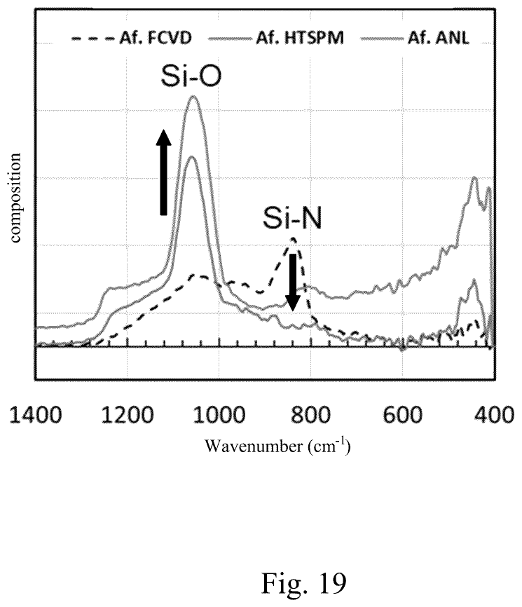

FIG. 19 illustrates a fourier-transform infrared spectroscopy (FTIR) showing the compositions of the isolation material (e.g., isolation material 210 or 240) and the isolation layers (e.g., isolation layers 211 or 241) in different stages. The horizontal axis presents different wave number corresponding to different bonds. As shown in FIG. 19, the dash-line illustrates the composition the isolation material after deposition of flowable dielectric material, wherein the formed flowable dielectric material includes S-O bonds and the Si-N bonds. In some embodiments, the formed flowable dielectric material may include compound of silicon, oxygen and nitrogen. The solid lines illustrate the composition of the isolation layers, which are formed by performing post-treatment process (e.g., HTSPM process or post=annealing process) and etching process on the isolation material, and the solid lines illustrate the concentration of the Si-N bonds is reduced and the concentration of the Si—O is increased. In some embodiments, the formed isolation layer may be silicon oxide, which is converted from the flowable dielectric material.

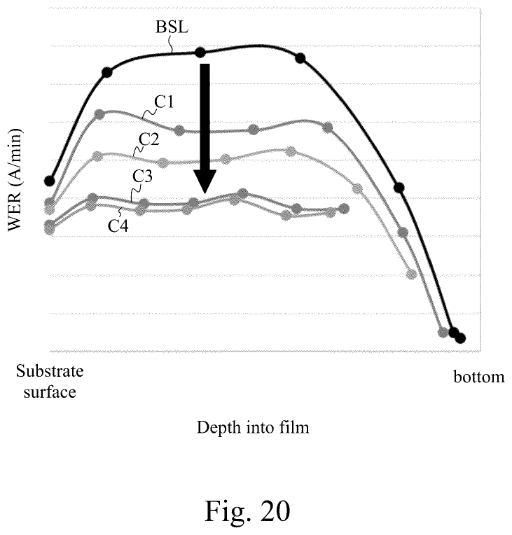

FIG. 20 is a plot diagram illustrating a comparison of wet etching rates (WER) among different conditions for the isolation regions 106 (e.g., STI oxide structure) and the refilled isolation layers 211/241. In this figure, the horizontal axis represents the depth of the isolation structures, and the vertical axis presents the WER.

As shown in FIG. 20, the baseline wet etching rate for standard shallow trench isolation (STI) regions, designated as isolation region 106, is shown by curve BSL. This baseline condition is established through a controlled process without additional post-treatment modifications. The curve C1 demonstrates the WER for refilled isolation layers 211 or 241 that have undergone one or more post-treatments (e.g., anneal processes) at a temperature 100° C. higher than the controlled baseline process temperature of isolation region 106. The curve C2 demonstrates the WER for refilled isolation layers 211 or 241 that have undergone one or more post-treatments (e.g., anneal processes) at a temperature 200° C. higher than the controlled baseline process temperature of isolation region 106. The curve C3 demonstrates the WER for refilled isolation layers 211 or 241 that have undergone one or more post-treatments (e.g., anneal processes) at a temperature 300° C. higher than the controlled baseline process temperature of isolation region 106. The curve C4 further explores the impact of elongated processing time; it represents a WER for refilled isolation layers 211 or 241 treated at a temperature 300° C. higher than the controlled baseline process temperature of baseline curve BSL, similar to C3, but with double the duration of the anneal post-treatment.

From the data presented in FIG. 20, it can be observed that the refilled isolation layers 211 or 241, corresponding to curves C1 through C4, exhibit lower WERs at certain depths when subjected to higher post-treatment anneal temperatures and/or extended annealing time duration compared to the baseline isolation region 106. This implies that post-treatment anneal conditions, especially elevated temperatures and increased time duration, can effectively improve the etch resistance of the isolation layers.

In FIG. 20, such improvement in structural density substantially reduces the WER of the isolation layers 211 or 241 with respect to the isolation regions 106. For example, a HT doping post-treatment to form HT the isolation layers 211 or 241 improves structural density of the dielectric material of the isolation layers 211 or 241, and such improvement in structural density substantially reduces the WER of the isolation layers 211 or 241 by about 30% to about 50% compared to the WER of the isolation regions 106 that are formed without the HT doping process.

According to one or more embodiments of the present disclosure, a method includes a number of operations. A plurality of isolation regions is formed between a plurality of fin structures over a substrate. A dummy gate structure is formed over the fin structures and the isolation regions. After forming the dummy gate structure, a first refilled isolation material is formed over the isolation regions. The first refilled isolation material is etched to form a plurality of first isolation layers having a top surface below top surfaces of the fin structures. A plurality of source/drain epitaxial structures is formed in the fin structures. The dummy gate structure is replaced with a gate structure. In one or more embodiments of the present disclosure, the first isolation layers have top surfaces more planar than bottom surfaces of the first isolation layers. In one or more embodiments of the present disclosure, first one of the first isolation layers has a top surface higher than a top surface of a second one of the first isolation layers. In one or more embodiments of the present disclosure, replacing the dummy gate structure includes removing the dummy gate structure to form a gate trench between gate spacers. The method further includes a number of operations. A second refilled isolation material is formed over the isolation regions within the gate trench. The second refilled isolation material is etched to form a plurality of second isolation layers having top surfaces below top surfaces of the fin structures. In one or more embodiments of the present disclosure, the method further includes before forming the first refilled isolation material, etching a plurality of source/drain recesses in the fin structures, and the plurality of the source/drain epitaxial structures is formed in the plurality of the source/drain recesses. In one or more embodiments of the present disclosure, the method further includes after the first isolation layers are formed, etching a plurality of source/drain recesses in the fin structures, and the plurality of the source/drain epitaxial structures is formed in the plurality of the source/drain recesses. In one or more embodiments of the present disclosure, the first refilled isolation material is formed by a flowable chemical vapor deposition process.

According to one or more embodiments of the present disclosure, a method includes a number of operations. A plurality of isolation regions is formed between a plurality of fin structures over a substrate. A dummy gate structure is formed over the fin structures and the isolation regions. Gate spacers are on either side of the dummy gate structure. A plurality of source/drain epitaxial structures is formed over the fin structures. The dummy gate structure is removed to form a gate trench between the gate spacers. A first isolation material formed in the gate trench. The first isolation material is etched to form a plurality of first isolation layers between the fin structures and over the isolation regions. After forming the plurality of first isolation layers, a gate structure is formed over the fin structures. In one or more embodiments of the present disclosure, the first isolation material is further formed over the gate spacers, and etching the first isolation material is performed such that the first isolation material is removed from top surfaces of the gate spacers. In one or more embodiments of the present disclosure, the method further includes forming an interlayer dielectric layer over the source/drain epitaxial structures, wherein the first isolation material is further formed over the interlayer dielectric layer, and etching the first isolation material is performed such that the first isolation material is removed from a top surface of the interlayer dielectric layer. In one or more embodiments of the present disclosure, the method further includes a number of operations. After forming the gate spacers and before removing the dummy gate structure, a second isolation material is formed over the fin structures and the isolation regions. The second isolation material is etched to form a plurality of second isolation layers between the fin structures and over the isolation regions. In some embodiments, the method further includes after forming the second isolation material, etching a plurality of source/drain recesses in the fin structures, wherein the source/drain epitaxial structures are formed in the source/drain recesses. In one or more embodiments of the present disclosure, the first isolation material is formed by a flowable chemical vapor deposition process.

According to one or more embodiments of the present disclosure, a device includes a plurality of fin structures over a substrate, a plurality of isolation regions between the fin structures, a gate structure over the fin structures, a plurality of source/drain epitaxial structures over the fin structures and a plurality of first isolation layers between the fin structures and over the isolation regions. The first isolation layers have top surfaces more planar than bottom surfaces of the first isolation layers. In one or more embodiments of the present disclosure, the first isolation layers overlap with the source/drain epitaxial structures but non-overlap with the gate structure. In one or more embodiments of the present disclosure, the first isolation layers overlap with the gate structure but non-overlap with the source/drain epitaxial structures. In one or more embodiments of the present disclosure, the method further includes a plurality of second isolation layers between the fin structures, wherein the first isolation layers are apart from the second isolation layers in a longitudinal direction of the fin structures. In one or more embodiments of the present disclosure, the top surfaces of the first isolation layers are lower than top surfaces of the fin structures. In one or more embodiments of the present disclosure, an oxygen concentration of the first isolation layers is less than an oxygen concentration the isolation regions. In one or more embodiments of the present disclosure, the method further includes an air gap between one of the source/drain epitaxial structures and one of the first isolation layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a plurality of isolation regions between a plurality of fin structures over a substrate;
forming a dummy gate structure over the fin structures and the isolation regions;
after forming the dummy gate structure, forming a first refilled isolation material over the isolation regions;
etching the first refilled isolation material to form a plurality of first isolation layers having a top surface below top surfaces of the fin structures;
forming a plurality of source/drain epitaxial structures in the fin structures; and
replacing the dummy gate structure with a gate structure.

2. The method of claim 1, wherein the first isolation layers have top surfaces more planar than bottom surfaces of the first isolation layers.

3. The method of claim 1, wherein first one of the first isolation layers has a top surface higher than a top surface of a second one of the first isolation layers.

4. The method of claim 1, wherein replacing the dummy gate structure comprises removing the dummy gate structure to form a gate trench between gate spacers, and the method further comprises:
forming a second refilled isolation material over the isolation regions within the gate trench; and
etching the second refilled isolation material to form a plurality of second isolation layers having top surfaces below top surfaces of the fin structures.

5. The method of claim 1, further comprising:
before forming the first refilled isolation material, etching a plurality of source/drain recesses in the fin structures, and the plurality of the source/drain epitaxial structures is formed in the plurality of the source/drain recesses.

6. The method of claim 1, further comprising:
after the first isolation layers are formed, etching a plurality of source/drain recesses in the fin structures, and the plurality of the source/drain epitaxial structures is formed in the plurality of the source/drain recesses.

7. The method of claim 1, wherein the first refilled isolation material is formed by a flowable chemical vapor deposition process.

8. A method comprising:
forming a plurality of isolation regions between a plurality of fin structures over a substrate;
forming a dummy gate structure over the fin structures and the isolation regions;
forming gate spacers on either side of the dummy gate structure;
forming a plurality of source/drain epitaxial structures over the fin structures;
removing the dummy gate structure to form a gate trench between the gate spacers;
forming a first isolation material in the gate trench;
etching the first isolation material to form a plurality of first isolation layers between the fin structures and over the isolation regions; and
after forming the plurality of first isolation layers, forming a gate structure over the fin structures.

9. The method of claim 8, wherein the first isolation material is further formed over the gate spacers, and etching the first isolation material is performed such that the first isolation material is removed from top surfaces of the gate spacers.

10. The method of claim 8, further comprising:
forming an interlayer dielectric layer over the source/drain epitaxial structures, wherein the first isolation material is further formed over the interlayer dielectric layer, and etching the first isolation material is performed such that the first isolation material is removed from a top surface of the interlayer dielectric layer.

11. The method of claim 8, further comprising:
after forming the gate spacers and before removing the dummy gate structure, forming a second isolation material over the fin structures and the isolation regions; and
etching the second isolation material to form a plurality of second isolation layers between the fin structures and over the isolation regions.

12. The method of claim 11, further comprising:
after forming the second isolation material, etching a plurality of source/drain recesses in the fin structures, wherein the source/drain epitaxial structures are formed in the source/drain recesses.

13. The method of claim 8, wherein the first isolation material is formed by a flowable chemical vapor deposition process.

14. A device comprising:
a plurality of fin structures over a substrate;
a plurality of isolation regions between the fin structures;
a gate structure over the fin structures;
a plurality of source/drain epitaxial structures over the fin structures; and
a plurality of first isolation layers between the fin structures and over the isolation regions, wherein the first isolation layers have top surfaces more planar than bottom surfaces of the first isolation layers.

15. The device of claim 14, wherein the first isolation layers overlap with the source/drain epitaxial structures but non-overlap with the gate structure.

16. The device of claim 14, wherein the first isolation layers overlap with the gate structure but non-overlap with the source/drain epitaxial structures.

17. The device of claim 14, further comprising:
a plurality of second isolation layers between the fin structures, wherein the first isolation layers are apart from the second isolation layers in a longitudinal direction of the fin structures.

18. The device of claim 14, wherein the top surfaces of the first isolation layers are lower than top surfaces of the fin structures.

19. The device of claim 14, wherein an oxygen concentration of the first isolation layers is less than an oxygen concentration the isolation regions.

20. The device of claim 14, further comprising:
an air gap between one of the source/drain epitaxial structures and one of the first isolation layers.
